(19) United States
(12) Patent Application Publication
(10) Pub. No.: US 2026/0093657 A1
(43) Pub. Date: Apr. 2, 2026

(54) CONFIGURABLE INPUT/OUTPUT (I/O) INTERFACE

(71) Applicants: Santosh Kumar, Telangana (IN); Chandra Mouli Raghumandal, Parvathipuram Manyam District (IN); Venkata Nittala, Rjahmundry (IN); Tirumala Sharma Penta, Rajahmundry (IN)

(72) Inventors: Santosh Kumar, Telangana (IN); Chandra Mouli Raghumandal, Parvathipuram Manyam District (IN); Venkata Nittala, Rjahmundry (IN); Tirumala Sharma Penta, Rajahmundry (IN)

(21) Appl. No.: 18/898,898

(22) Filed: Sep. 27, 2024

(51) Int. Cl. G06F 13/42; H01L 27/02

(52) U.S. Cl. CPC G06F 13/4282; H10D 89/811; H10D 89/911; G06F 2213/0042

(57) ABSTRACT

An apparatus includes a driver stage comprising a pull-up driver circuit coupled to a pull-down driver circuit. The apparatus includes a driver-supporting circuit coupled to the pull-up driver circuit and the pull-down driver circuit. The apparatus includes a resistor ladder coupled to the driver-supporting circuit. The apparatus includes an electrostatic discharge (ESD) protection circuitry coupled to the resistor ladder and an input/output (I/O) pad.

### BACKGROUND

Automotive applications may include low-speed I/O interfaces operating at higher supply voltages (e.g., 5V). However, designing and configuring general-purpose I/O (GPIO) interfaces to support 5V Inter-Integrated Circuit (I2C) communications along with 3.3V/1.8V GPIO mode is challenging.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings listed below.

FIG. 1 is a block diagram of a driver architecture based on the disclosed techniques, in accordance with some embodiments.

FIG. 2 is a block diagram of a Vn generation circuit, in accordance with some embodiments.

FIG. 3 illustrates a diagram of signal graphs for Vpad, 3.7_pad, and Vn voltages, in accordance with some embodiments.

FIG. 4 is a block diagram of a receiver using Vn bias voltage, in accordance with some embodiments.

FIG. 5 is a block diagram of a Vnw generation circuit, in accordance with some embodiments.

FIG. 6 illustrates a diagram of signal graphs for Vpad, 3.7_pad, Vp_prot, ngate2, and Vnw voltages, in accordance with some embodiments.

FIG. 7 is a block diagram of an Ngate2 generation circuit, in accordance with some embodiments.

FIG. 8 illustrates a diagram of signal graphs for Vpad, 3.7_pad, and ngate2 voltages, in accordance with some embodiments.

FIG. 9 is a block diagram of a lvl-up circuit, in accordance with some embodiments.

FIG. 10 is a block diagram of a Vp generation circuit (1p8 mode with Vpad=1.8V), in accordance with some embodiments.

FIG. 11 is a block diagram of a Vp generation circuit (1p8 mode with Vpad=0V), in accordance with some embodiments.

FIG. 12 is a block diagram of a Vp generation circuit (3p3 mode with Vpad=3.3V), in accordance with some embodiments.

FIG. 13 is a block diagram of a Vp generation circuit (3p3 mode with Vpad=0V), in accordance with some embodiments.

FIG. 14 is a block diagram of a Vp generation circuit (5V-I2C mode with FS=1 and Vpad=5V), in accordance with some embodiments.

FIG. 15 is a block diagram of a Vp generation circuit (5V-I2C mode with FS=0 and Vpad-0.4V), in accordance with some embodiments.

FIG. 16 is a flow diagram of an example method for manufacturing a GPIO interface, in accordance with some embodiments.

FIG. 17 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for those of other embodiments. Embodiments outlined in the claims encompass all available equivalents of those claims.

As used herein, the term “chip” (or die) refers to a piece of a material, such as a semiconductor material, that includes a circuit, such as an integrated circuit or a part of an integrated circuit. The term “memory IP” indicates memory intellectual property. The terms “memory IP,” “memory device,” “memory chip,” and “memory” are interchangeable.

The term “a processor” configured to carry out specific operations includes both a single processor configured to carry out all of the operations (e.g., operations or methods disclosed herein) as well as multiple processors individually configured to carry out some or all of the operations (which may overlap) such that the combination of processors carry out all of the operations.

As used herein, the term “IO” indicates input/output. As used herein, the term “R-C” indicates resistance and capacitance. As used herein, the term “Rx” indicates receiver (or receive). As used herein, the term “Tx” indicates transmitter (or transmit). As used herein, the term “TRX” indicates transceiver. As used herein, the term “UCle” indicates Universal Chiplet Interconnect Express. As used herein, the term “Vref” indicates reference voltage. As used herein, the term “Vin” indicates input voltage. As used herein, the terms “serially coupled,” “serially connected,” and “connected in series” are synonymous to each other and indicate a serial connection between two or more components/circuits where the serial connection can be based on a direct or indirect electrical connection between the two or more components/circuits. As used herein, the terms “parallel coupled,” “parallel connected,” and “connected in parallel” are synonymous to each other and indicate a parallel connection between two or more components/circuits where the parallel connection can be based on a direct or indirect electrical connection between the two or more components/circuits.

The disclosed techniques include configurations for a GPIO interface that supports both 1.8V and 3.3V rail voltage using devices that are tolerable for 1.8V (e.g., the device junction limits, such as gate-source, gate-drain, drain-bulk, and gate-bulk support a maximum of 1.8V across the junctions). The disclosed GPIO configurations can also support a pad voltage of up to 5V I2C using transistor devices with a maximum junction voltage tolerance of approximately about 1.98V. In this regard, the disclosed GPIO interfaces can be configured to operate with, for example, supply voltages of 1.8V, 3.3V, and 5V.

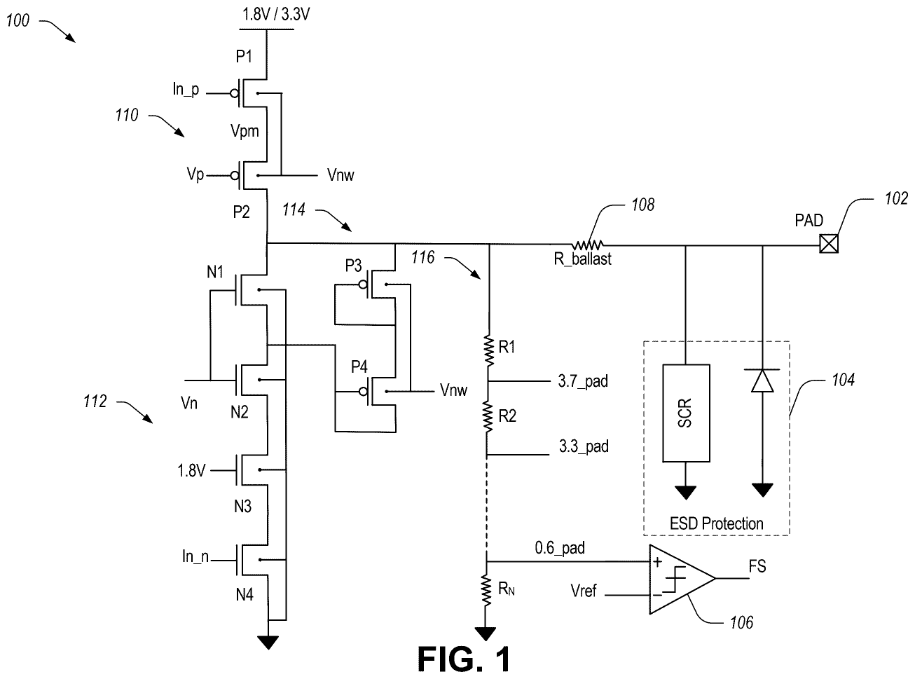

FIG. 1 is a block diagram of a driver architecture 100 based on the disclosed techniques, in accordance with some embodiments. Referring to FIG. 1, driver architecture 100 includes PMOS transistors P1-P2 configured as a pull-up driver circuit 110, NMOS transistors N1-N4 configured as a pull-down driver circuit 112, PMOS transistors P3-P4 configured as a driver-supporting circuit 114, resistor ladder 116, a ballast resistor 108, an electrostatic discharge (ESD) protection circuit 104, and an I/O pad 102.

In some aspects, the resistor ladder 116 includes resistors R1, R2, . . . , Rn and at least one failsafe comparator 106. In some aspects, the failsafe comparator can be used to trigger a shut-down of driver architecture 100 when the voltage at I/O pad 102 exceeds 5V.

In some aspects, the ESD protection circuit 104 includes a silicon-controlled rectifier (SCR) circuit.

In some aspects, the transistor devices in the driver architecture 100 are 1.98V-tolerant thick gate devices.

The suggested I/O solution (e.g., driver architecture 100) is tolerant to 5.5V on the I/O pad 102 in I²C mode, where the I2C bus is pulled up by an external resistor to 5V (5.5V worst case). In some aspects, the I/O supply voltage in 5V I²C mode can be 3.3V. The same I/O can be re-configured to 3.3V/1.8V GPIO mode. The I/O with multi-configuration and multi-supply support with 5.5V pad voltage tolerance enables the support for various automotive-related applications.

In driver architecture 100 of FIG. 1, bias voltages Vp, Vnw, and Vn can be configured based on one or more of the following:
(a) I/O mode (e.g., GPIO/I²C);
(b) I/O supply voltage (e.g., 3.3V or 1.8V); and
(c) Pad logic voltage level.

The following Table 1 lists expected voltage bias voltages for different operating mode scenarios:

TABLE 1

| | Pad | | Vn | | Vnw | | Vp | |
|---|---|---|---|---|---|---|---|---|
| | Logic | Logic | Vpad@ | Vpad@ | Vpad@ | Vpad@ | Vpad@ | Vpad@ |
| MODE | 0 | 1 | 0 | 1 | 0 | 1 | 0 | 1 |
| 1p8_GPIO | 0 | 1.8 V | 1.8 V | 1.8 V | 1.8 V | 1.8 V | 0 | 0 |
| 3p3_GPIO | 0 | 3.3 V | 1.8 V | 2.4 V | 3.3 V | 3.3 V | 1.8 V | 1.8 V |
| 5 V_I2C | 0.4 V | 5 V | 1.8 V | 3.7 V | 3.3 V | 5 V | 1.8 V | 5 V |

The indicated bias voltages ensure that none of the transistors are violating the maximum allowed junction voltage limit (e.g., 1.98V). It can be observed from the above Table 1 that node Vp voltage can be varied from 0V to 5V depending on the scenario. Similarly, Vnw and Vn node voltages can be changed.

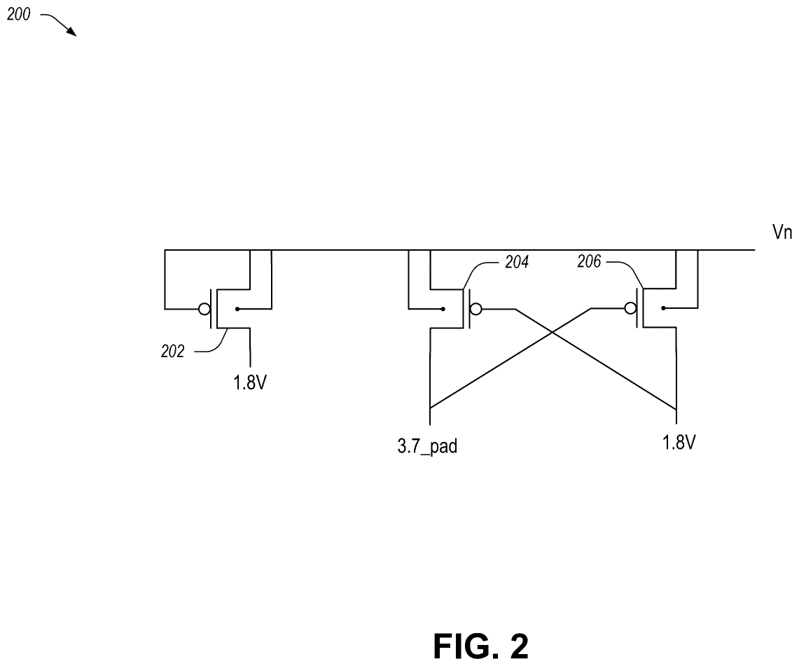

The description below of FIGS. 2-15 provide the details of the following circuits that generate these bias voltages: a Vn generation circuit, a receiver using Vn bias voltage, a Vnw generation circuit, a Ngate2 generation circuit, a Lvl-up circuit, a Vp generation circuit (1.8V GPIO mode), a Vp generation circuit (3.3V GPIO mode), and a Vp generation circuit (5V I²C mode).

FIG. 2 is a block diagram of a Vn generation circuit 200, in accordance with some embodiments. Referring to FIG. 2, the Vn generation circuit 200 includes PMOS transistors 202, 204, and 206 configured as illustrated in FIG. 2, using the 1.8V and 3.7_pad voltage rail (as provided by the resistor ladder 116).

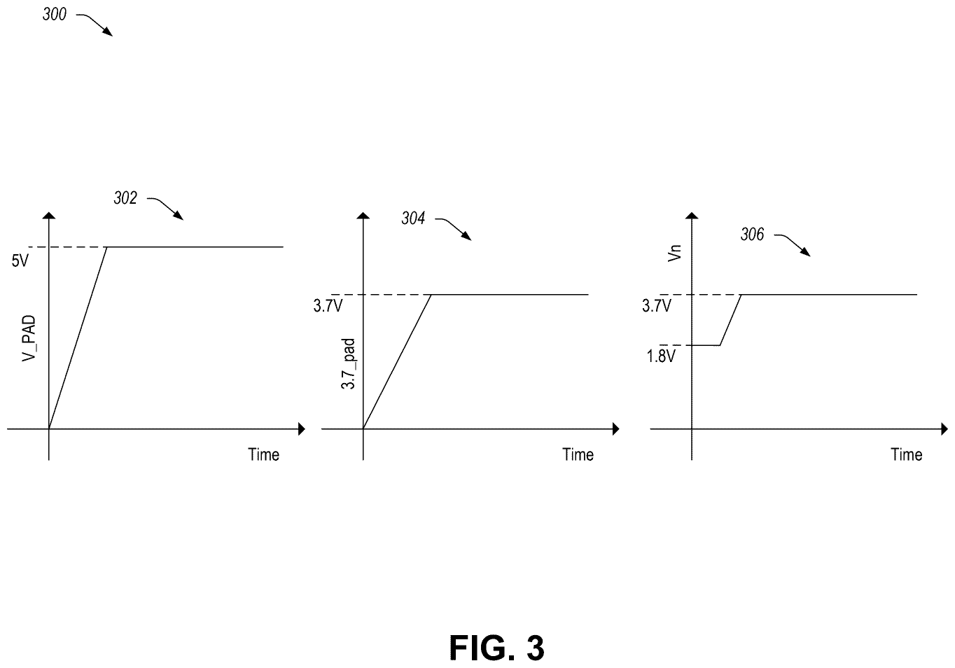

FIG. 3 illustrates a diagram 300 of signal graphs 302, 304, and 306 for Vpad, 3.7_pad, and Vn voltages, in accordance with some embodiments.

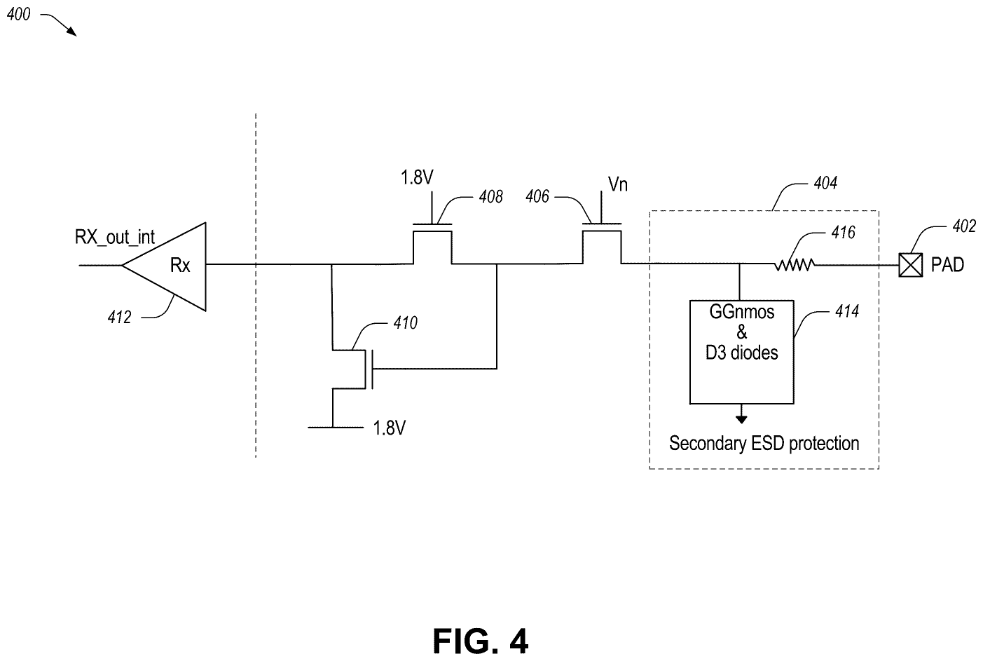

FIG. 4 is a block diagram 400 of a receiver using Vn bias voltage, in accordance with some embodiments. Referring to FIG. 4, receiver 412 is coupled to I/O pad 402 via an ESD protection circuit 404 and NMOS transistors 406, 408, and 410. The NMOS transistors are connected to 1.8V and Vn voltage terminals, as illustrated in FIG. 4.

In some aspects, the ESD protection circuit 404 includes a resistor 416 and NMOS-diodes circuit 414.

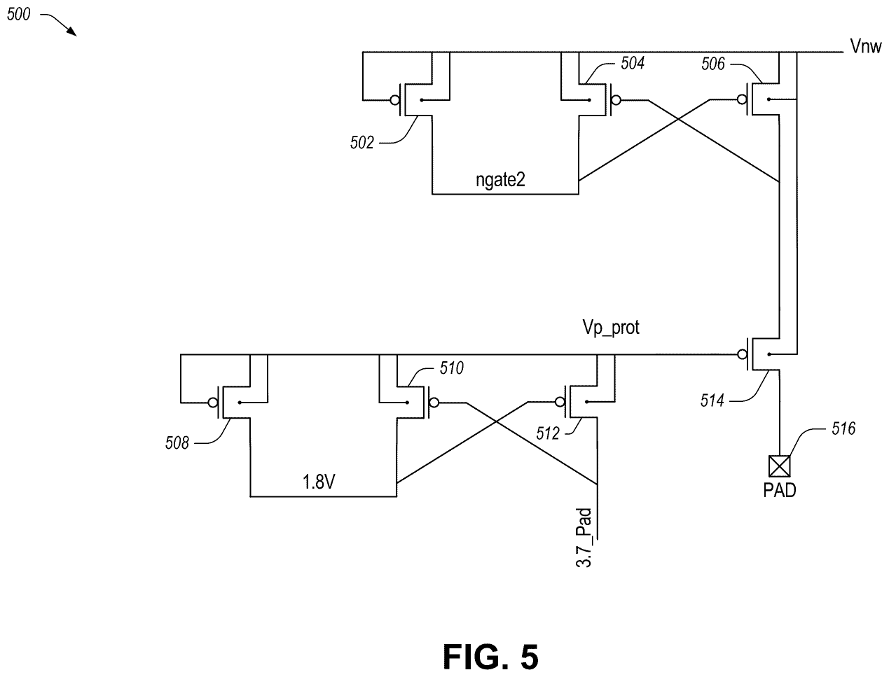

FIG. 5 is a block diagram of a Vnw generation circuit 500, in accordance with some embodiments. Referring to FIG. 5, the Vnw generation circuit includes an I/O pad 516 and PMOS transistors 502, 504, 506, 508, 510, 512, and 514 coupled as illustrated in FIG. 5. As illustrated in FIG. 5, the PMOS transistors use 1.8V, 3.7_pad, and ngate2 voltage rails.

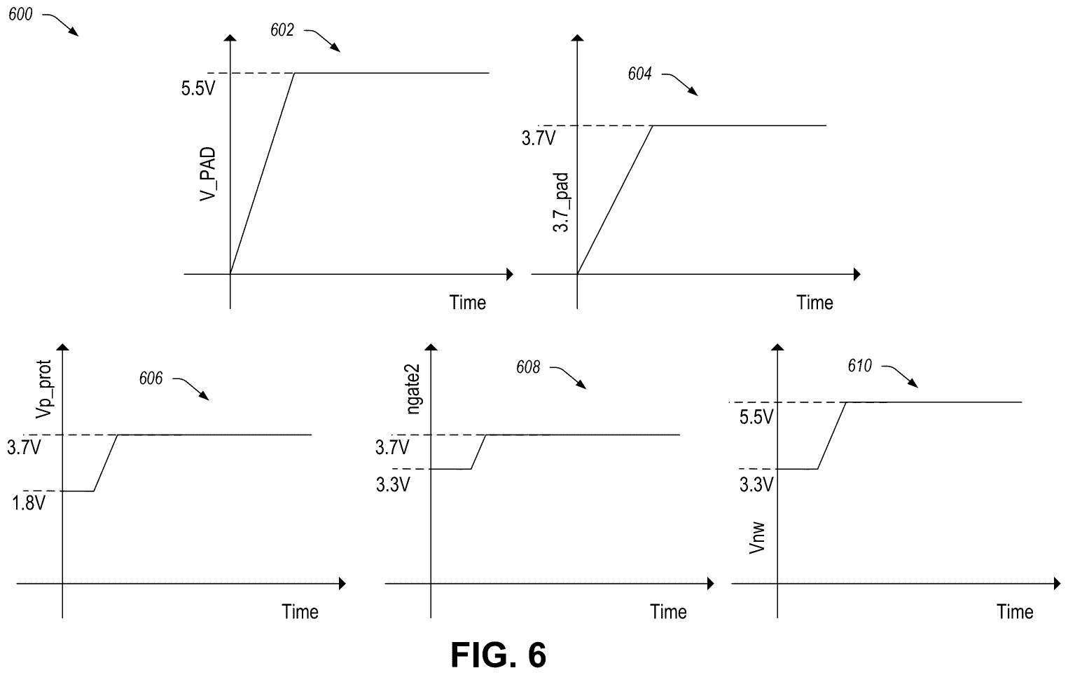

FIG. 6 illustrates diagram 600 of signal graphs 602, 604, 606, 608, and 610 for Vpad, 3.7_pad, Vp_prot, Ngate2, and Vnw voltages, in accordance with some embodiments.

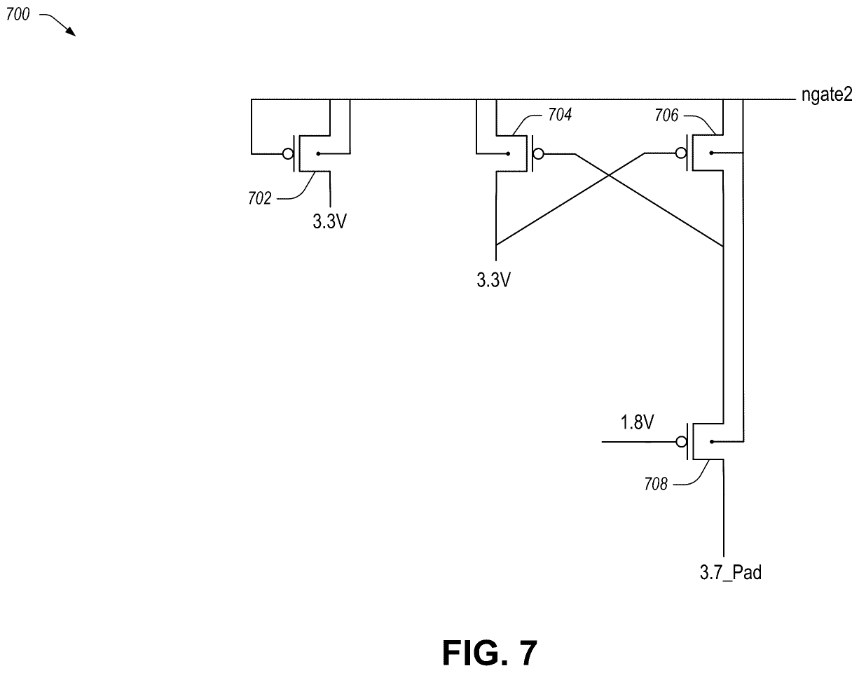

FIG. 7 is a block diagram of a Ngate2 generation circuit 700, in accordance with some embodiments. Referring to FIG. 7, the Ngate 2 generation circuit 700 includes PMOS transistors 702, 704, 706, and 708 coupled to 3.3V, 1.8V, and 3.7_pad voltage rails as illustrated in FIG. 7.

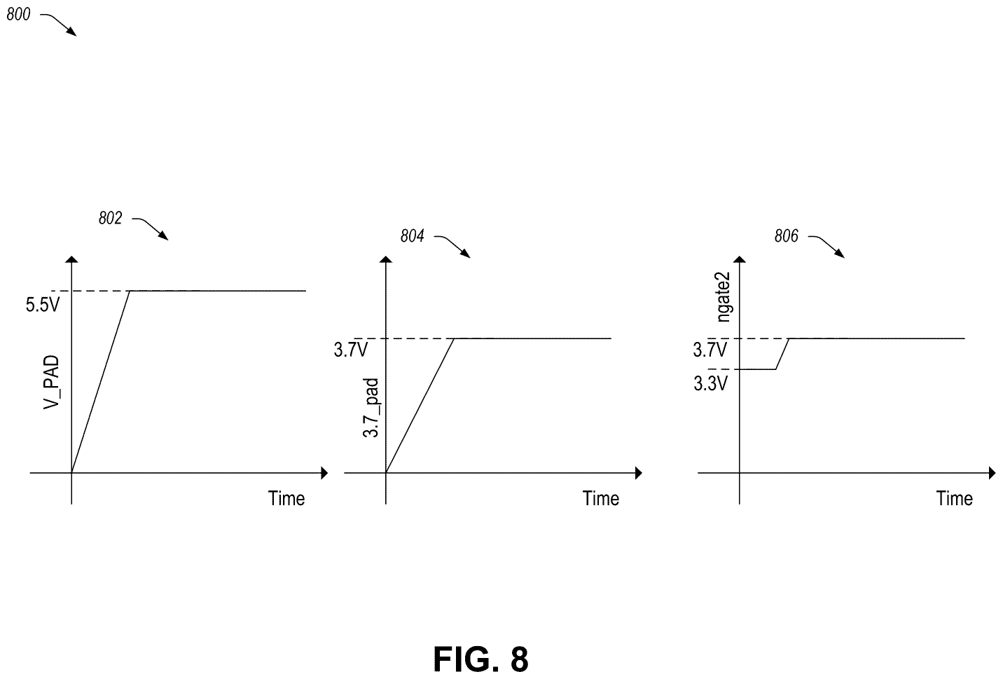

FIG. 8 illustrates diagram 800 of signal graphs 802, 804, and 806 for Vpad, 3.7_pad, and ngate2 voltages, in accordance with some embodiments.

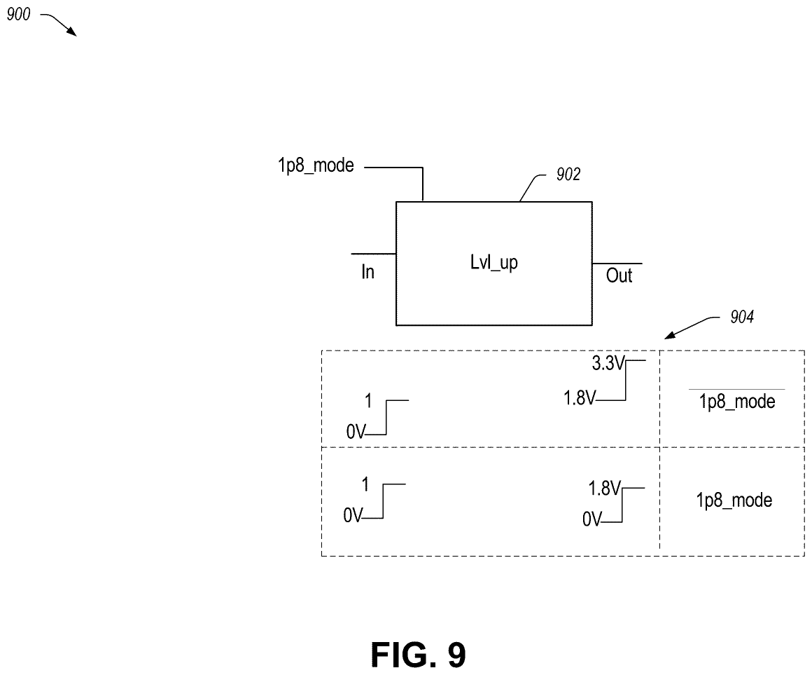

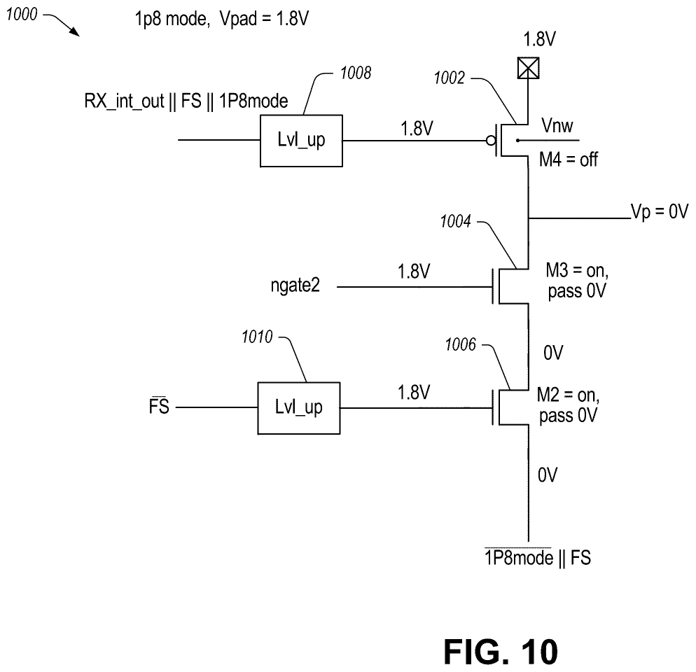

FIG. 9 is a block diagram 900 of a Lvl_up circuit 902, in accordance with some embodiments. Referring to FIG. 9, the Lvl_up circuit can be configured to operate with corresponding signal processing characteristics in one of at least two operating modes (e.g., 1p8_mode and 1p8_mode_bar), as illustrated in table 904. In some aspects, the Lvl_up circuit 902 can be used in the circuits of FIGS. 10-15.

FIG. 10 is a block diagram of a Vp generation circuit 1000 (1p8 mode with Vpad=1.8V), in accordance with some embodiments. Referring to FIG. 10, Vp generation circuit 1000 includes a PMOS transistor 1002, Lvl_up circuits 1008 and 1010, and NMOS transistors 1004 and 1006. The pad voltage, device voltages, and operating mode are illustrated in FIG. 10.

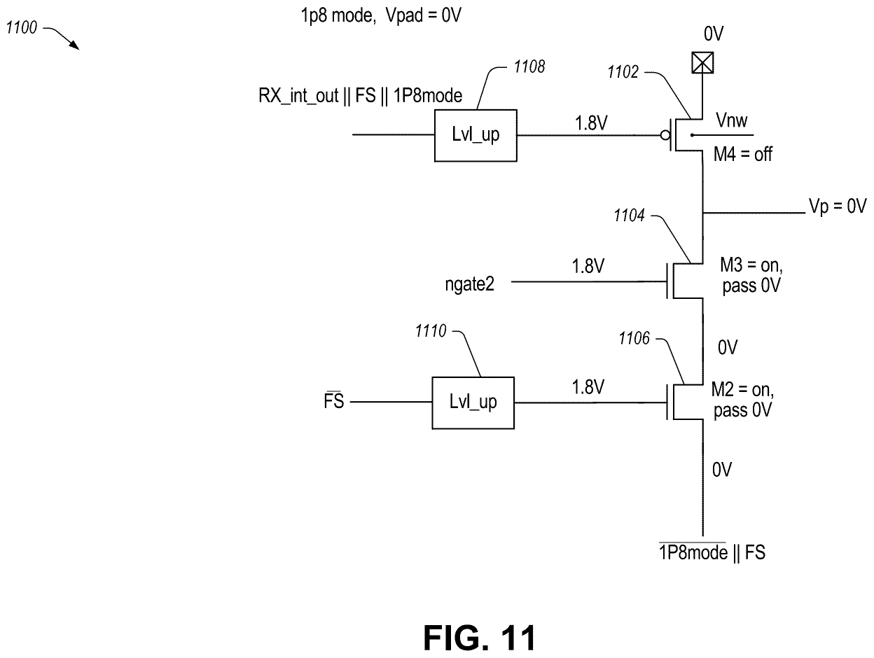

FIG. 11 is a block diagram of a Vp generation circuit 1100 (1p8 mode with Vpad=0V), in accordance with some embodiments. Referring to FIG. 11, Vp generation circuit 1100 includes a PMOS transistor 1102, Lvl_up circuits 1108 and 1110, and NMOS transistors 1104 and 1106. The pad voltage, device voltages, and operating mode are illustrated in FIG. 11.

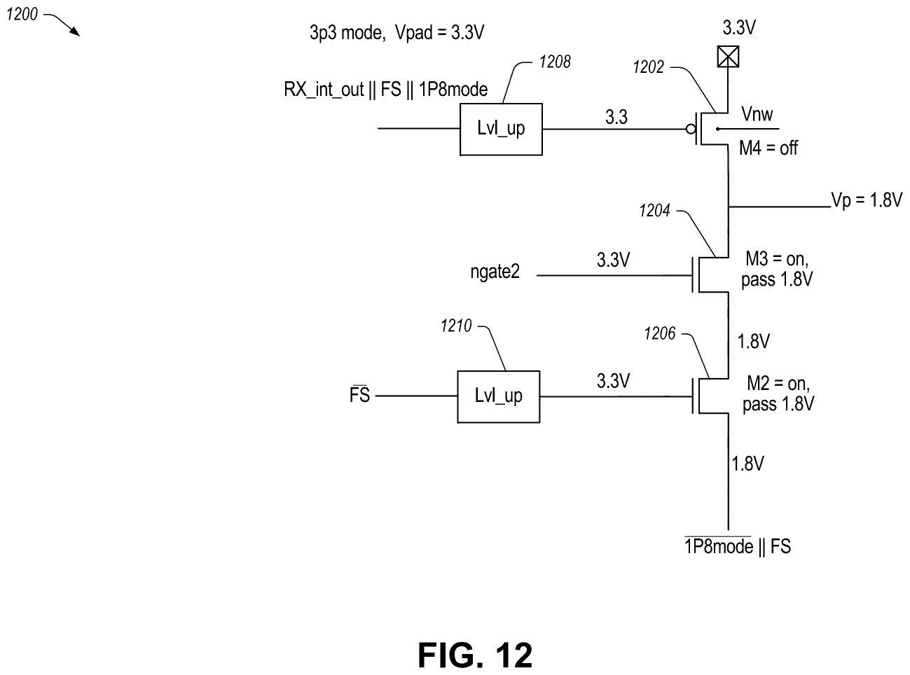

FIG. 12 is a block diagram of a Vp generation circuit (3p3 mode with Vpad=3.3V), in accordance with some embodiments. Referring to FIG. 12, Vp generation circuit 1200 includes a PMOS transistor 1202, Lvl_up circuits 1208 and 1210, and NMOS transistors 1204 and 1206. The pad voltage, device voltages, and operating mode are illustrated in FIG. 12.

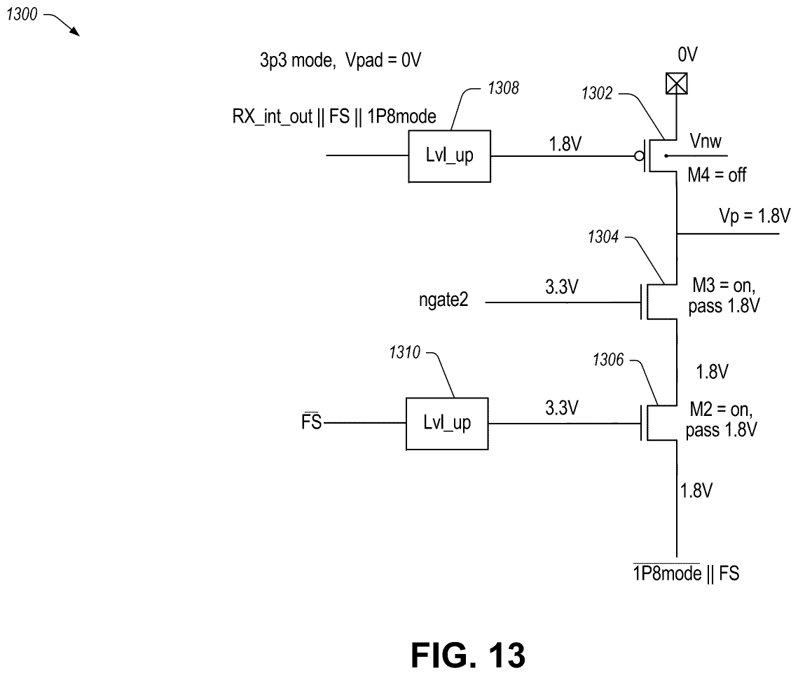

FIG. 13 is a block diagram of a Vp generation circuit 1300 (3p3 mode with Vpad=0V), in accordance with some embodiments. Referring to FIG. 13, Vp generation circuit 1300 includes a PMOS transistor 1302, Lvl_up circuits 1308 and 1310, and NMOS transistors 1304 and 1306. The pad voltage, device voltages, and operating mode are illustrated in FIG. 13.

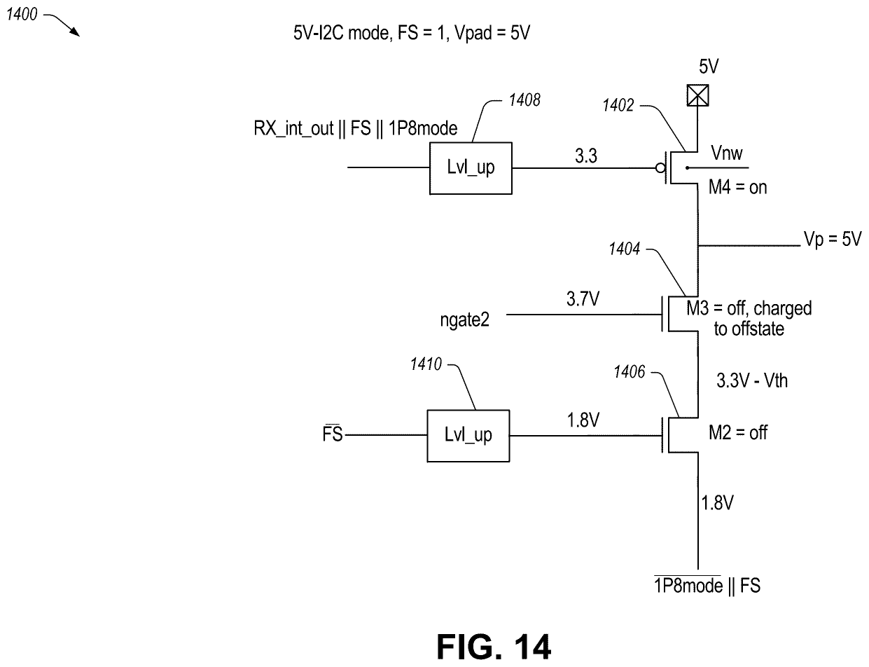

FIG. 14 is a block diagram of a Vp generation circuit 1400 (5V-I²C mode with FS=1 and Vpad=5V), in accordance with some embodiments. Referring to FIG. 14, Vp generation circuit 1400 includes a PMOS transistor 1402, Lvl_up circuits 1408 and 1410, and NMOS transistors 1404 and 1406. The pad voltage, device voltages, and operating mode are illustrated in FIG. 14.

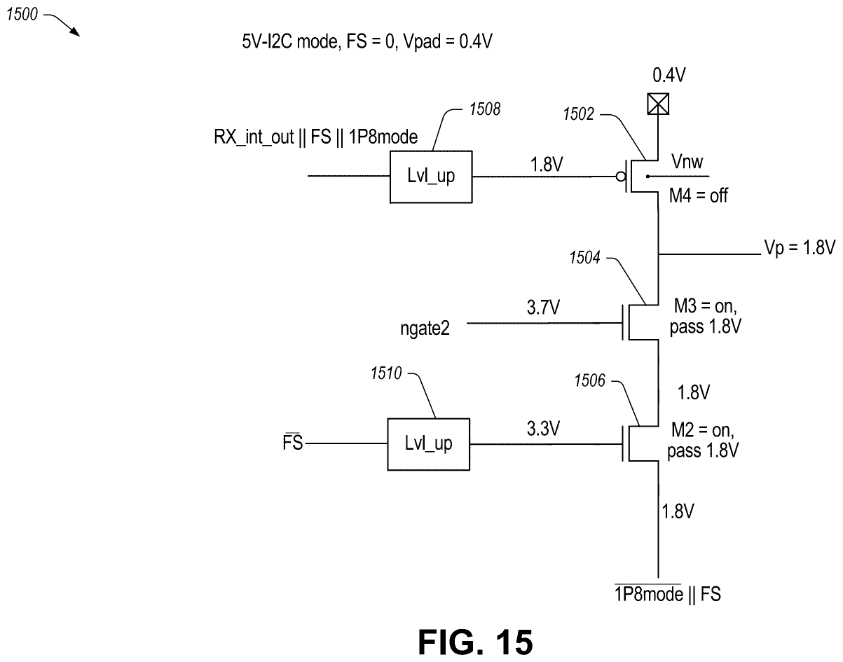

FIG. 15 is a block diagram of a Vp generation circuit 1500 (5V-I²C mode with FS=0 and Vpad=0.4V), in accordance with some embodiments. Referring to FIG. 15, Vp generation circuit 1500 includes a PMOS transistor 1502, Lvl_up circuits 1508 and 1510, and NMOS transistors 1504 and 1506. The pad voltage, device voltages, and operating mode are illustrated in FIG. 15.

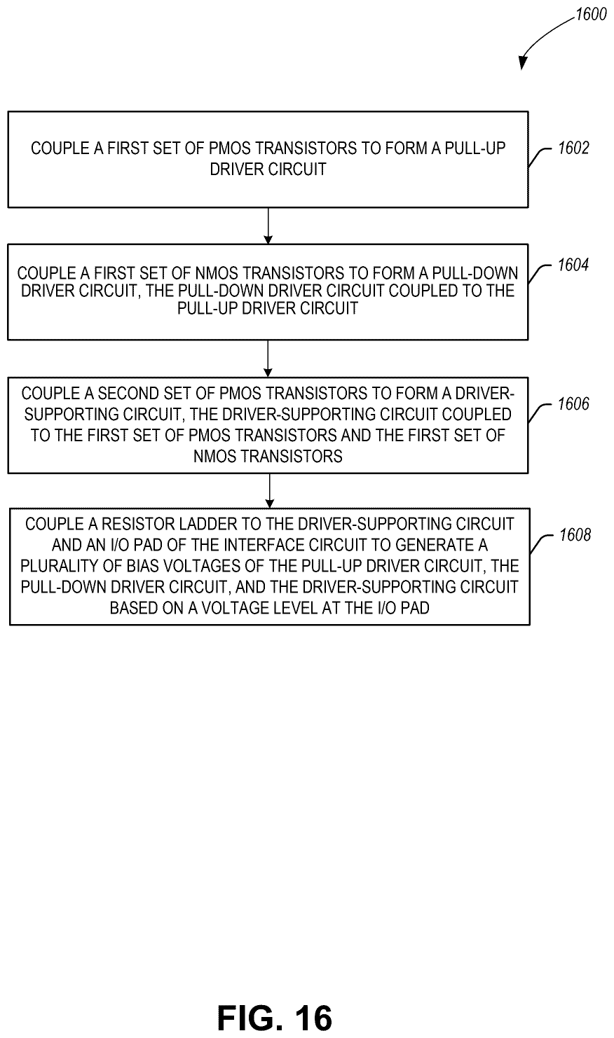

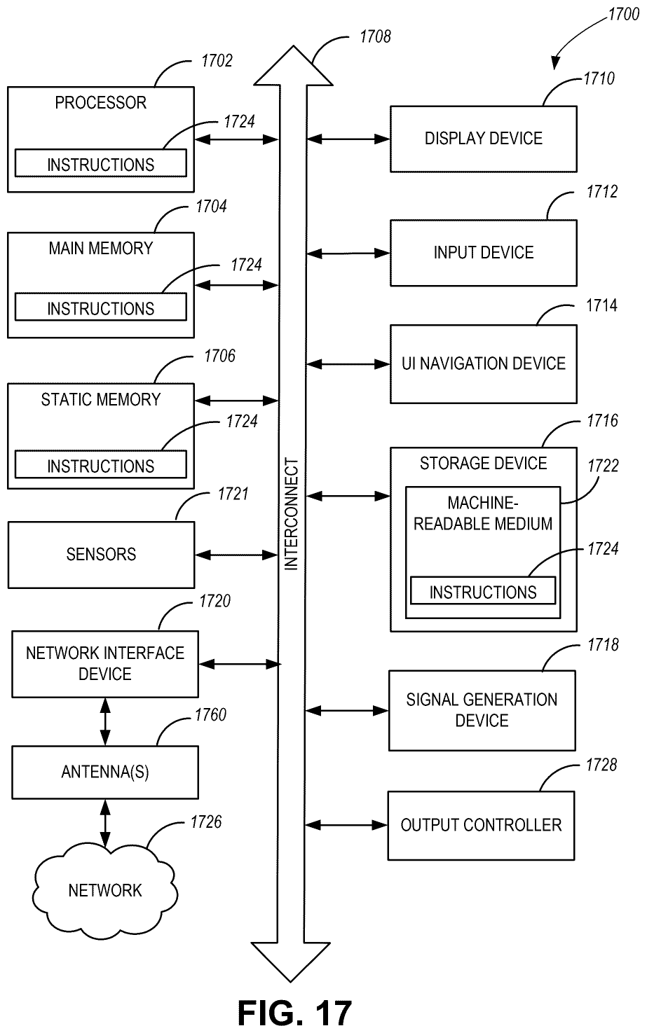

FIG. 16 is a flow diagram of an example method 1600 for manufacturing a GPIO interface, in accordance with some embodiments. Referring to FIG. 16, method 1600 includes operations 1602, 1604, 1606, and 1608, which may be executed by a processor, an embedded controller, a receiver circuit, a transceiver circuit, or another processor of a computing device (e.g., hardware processor 1702 of machine 1700 illustrated in FIG. 17, which can include one or more of the circuits discussed in connection with FIGS. 1-15). In some embodiments, one or more of the circuits discussed in connection with FIGS. 1-15 can perform the functionalities (or include the configurations or circuitry) associated with FIG. 16, as well as one or more of the examples listed below.

At operation 1602, a first set of PMOS transistors (e.g., P1 and P2 in FIG. 1) are coupled to form a pull-up driver circuit 110.

At operation 1604, a first set of NMOS transistors (e.g., N1-N4 in FIG. 1) are coupled to form a pull-down driver circuit 112. The pull-down driver circuit is coupled to the pull-up driver circuit.

At operation 1606, a second set of PMOS transistors (e.g., P3 and P4 in FIG. 1) are coupled to form a driver-supporting circuit (e.g., driver-supporting circuit 114). The driver-supporting circuit is coupled to the first set of PMOS transistors and the first set of NMOS transistors.

At operation 1608, a resistor ladder is coupled to the driver-supporting circuit and an input/output (I/O) pad of the interface circuit to generate a plurality of bias voltages of the pull-up driver circuit, the pull-down driver circuit, and the driver-supporting circuit based on a voltage level at the I/O pad of the interface circuit.

FIG. 17 illustrates a block diagram of an example machine 1700 upon which any one or more of the techniques (e.g., methodologies) discussed herein may perform. In alternative embodiments, the machine 1700 may operate as a standalone device or may be connected (e.g., networked) to other machines. In a networked deployment, machine 1700 may operate in the capacity of a server machine, a client machine, or both in server-client network environments. In an example, machine 1700 may function as a peer machine in a peer-to-peer (P2P) (or other distributed) network environment. The machine 1700 may be a personal computer (PC), a tablet PC, a set-top box (STB), a personal digital assistant (PDA), a portable communications device, a mobile telephone, a smartphone, a web appliance, a network router, switch or bridge, or any other computing device capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The terms “machine,” “computing device,” and “computer system” are used interchangeably.

Machine (e.g., computer system) 1700 may include a hardware processor 1702 (e.g., a central processing unit (CPU), a graphics processing unit (GPU), a hardware processor core, or any combination thereof), a main memory 1704, and a static memory 1706, some or all of which may communicate with each other via an interlink (e.g., bus) 1708. In some aspects, the main memory 1704, the static memory 1706, or any other type of memory (including cache memory) used by machine 1700 can be configured based on the disclosed techniques or can implement the disclosed memory devices.

Specific examples of main memory 1704 include Random Access Memory (RAM) and semiconductor memory devices, which may include, in some embodiments, storage locations in semiconductors such as registers. Specific examples of static memory 1706 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 1700 may further include a display device 1710, an input device 1712 (e.g., a keyboard), and a user interface (UI) navigation device 1714 (e.g., a mouse). In an example, the display device 1710, the input device 1712, and the UI navigation device 1714 may be a touchscreen display. The machine 1700 may additionally include a storage device (e.g., drive unit or another mass storage device) 1716, a signal generation device 1718 (e.g., a speaker), a network interface device 1720, and one or more sensors 1721, such as a global positioning system (GPS) sensor, compass, accelerometer, or other sensors. The machine 1700 may include an output controller 1728, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the hardware processor 1702 and/or instructions 1724 may comprise processing circuitry and/or transceiver circuitry.

The storage device 1716 may include a machine-readable medium 1722 on which one or more sets of data structures or instructions 1724 (e.g., software) embodying or utilized by any one or more of the techniques or functions described herein can be stored. Instructions 1724 may also reside, completely or at least partially, within the main memory 1704, within static memory 1706, or the hardware processor 1702 during execution thereof by machine 1700. In an example, one or any combination of the hardware processor 1702, the main memory 1704, the static memory 1706, or the storage device 1716 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 1722 is illustrated as a single medium, the term “machine-readable medium” may include a single medium or multiple media (e.g., a centralized or distributed database and/or associated caches and servers) configured to store instructions 1724.

An apparatus of machine 1700 may be one or more of a hardware processor 1702 (e.g., a central processing unit (CPU), a graphics processing unit (GPU), a hardware processor core, or any combination thereof), a main memory 1704 and a static memory 1706, one or more sensors 1721, a network interface device 1720, one or more antennas 1760, a display device 1710, an input device 1712, a UI navigation device 1714, a storage device 1716, instructions 1724, a signal generation device 1718, and an output controller 1728. The apparatus may be configured to perform one or more of the methods and/or operations disclosed herein. The apparatus may be intended as a component of machine 1700 to perform one or more of the methods and/or operations disclosed herein and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by machine 1700 and that causes machine 1700 to perform any one or more of the techniques of the present disclosure or that is capable of storing, encoding, or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 1724 may further be transmitted or received over a communications network 1726 using a transmission medium via the network interface device 1720 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.8.4 family of standards, a Long Term Evolution (LTE) family of standards, a Universal Mobile Telecommunications System (UMTS) family of standards, peer-to-peer (P2P) networks, among others.

In an example, the network interface device 1720 may include one or more physical jacks (e.g., Ethernet, coaxial, or phone jacks) or one or more antennas to connect to the communications network 1726. In an example, the network interface device 1720 may include one or more antennas 1760 to wirelessly communicate using at least one single-input multiple-output (SIMO), multiple-input multiple-output (MIMO), or multiple-input single-output (MISO) techniques. In some examples, the network interface device 1720 may wirelessly communicate using multiple-user MIMO techniques. The term “transmission medium” shall be taken to include any intangible medium that can store, encode, or carry instructions for execution by machine 1700 and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a particular manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part, all, or any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at separate times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random access memory (RAM), magnetic disk storage media, optical storage media, flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, examples that include the elements shown or described are also contemplated. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc., are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments, such as part of a system on chip, a set of intercommunicating functional blocks, or similar, although the scope of the disclosure is not limited in this respect.

Described implementations of the subject matter can include one or more features, alone or in combination, as illustrated below by way of examples.

Example 1 is an interface circuit comprising: a first PMOS transistor comprising a drain terminal coupled to rail voltage; a second PMOS transistor comprising a drain terminal coupled to a source terminal of the first PMOS transistor, and a bulk terminal of the first PMOS transistor coupled to a bulk terminal of the second PMOS transistor; a third PMOS transistor comprising a drain terminal coupled to a source terminal of the second PMOS transistor; and a fourth PMOS transistor comprising a drain terminal coupled to a source terminal and a gate terminal of the third PMOS transistor.

In Example 2, the subject matter of Example 1 includes, a first NMOS transistor comprising a drain terminal coupled to the source terminal of the second PMOS transistor and the drain terminal of the third PMOS transistor.

In Example 3, the subject matter of Example 2 includes, a second NMOS transistor comprising a drain terminal coupled to a source terminal of the first NMOS transistor and a gate terminal coupled to a gate terminal of the first NMOS transistor.

In Example 4, the subject matter of Example 3 includes, wherein a gate terminal and a source terminal of the fourth PMOS transistor are coupled to the drain terminal of the second NMOS transistor.

In Example 5, the subject matter of Examples 3-4 includes, a third NMOS transistor comprising a drain terminal coupled to a source terminal of the second NMOS transistor.

In Example 6, the subject matter of Example 5 includes, a fourth NMOS transistor comprising a drain terminal coupled to a source terminal of the second NMOS transistor.

In Example 7, the subject matter of Example 6 includes, wherein a source terminal of the fourth NMOS transistor, a bulk terminal of the first NMOS transistor, a bulk terminal of the second NMOS transistor, a bulk terminal of the third NMOS transistor, and a bulk terminal of the fourth NMOS transistor are coupled to each other.

In Example 8, the subject matter of Example 7 includes, wherein a gate terminal of the second PMOS transistor is coupled to a first bias voltage, and a gate terminal of the second NMOS transistor is coupled to a second bias voltage.

In Example 9, the subject matter of Example 8 includes, wherein a bulk terminal of the third PMOS transistor, a bulk terminal of the fourth PMOS transistor, the bulk terminal of the first PMOS transistor, and the bulk terminal of the second PMOS transistor are coupled to a third bias voltage.

In Example 10, the subject matter of Example 9 includes, a first bias voltage generation circuit coupled to the gate terminal of the second PMOS transistor; a second bias voltage generation circuit coupled to the gate terminal of the second NMOS transistor; and a third bias voltage generation circuit coupled to the bulk terminal of the third PMOS transistor.

In Example 11, the subject matter of Examples 1-10 includes, a resistor ladder coupled to the drain terminal of the third PMOS transistor; and a pad terminal coupled to the resistor ladder via a ballast resistor.

In Example 12, the subject matter of Examples 6-11 includes, wherein the interface circuit comprises a system-on-chip (SoC), the SoC comprising an integrated circuit (IC), the IC comprising at least two transistors of the first PMOS transistor, the second PMOS transistor, the third PMOS transistor, the fourth PMOS transistor, the first NMOS transistor, the second NMOS transistor, the third NMOS transistor, and the fourth NMOS transistor.

In Example 13, the subject matter of Example 12 includes, wherein the SoC further comprises at least one connector, and wherein the at least one connector conforms with at least one of Universal Serial Bus (USB), High-Definition Multimedia Interface (HDMI), Thunderbolt, Peripheral Component Interconnect Express (PCIe), and Ethernet specifications.

Example 14 is an apparatus comprising: a driver stage comprising a pull-up driver circuit coupled to a pull-down driver circuit; a driver-supporting circuit coupled to the pull-up driver circuit and the pull-down driver circuit; a resistor ladder coupled to the driver-supporting circuit; and an electrostatic discharge (ESD) protection circuitry coupled to the resistor ladder and an input/output (I/O) pad.

In Example 15, the subject matter of Example 14 includes, a first bias voltage generation circuit coupled to the pull-up driver circuit, the first bias voltage generation circuit to generate a first bias voltage for the pull-up driver circuit based on a voltage level at the I/O pad.

In Example 16, the subject matter of Example 15 includes, a second bias voltage generation circuit coupled to the pull-down driver circuit, the second bias voltage generation circuit to generate a second bias voltage for the pull-down driver circuit based on the voltage level at the I/O pad.

In Example 17, the subject matter of Example 16 includes, a third bias voltage generation circuit coupled to the pull-up driver circuit and the driver-supporting circuit, the third bias voltage generation circuit to generate a third bias voltage for bulk terminals of the pull-up driver circuit and the driver-supporting circuit based on the voltage level at the I/O pad.

In Example 18, the subject matter of Example 17 includes, wherein the resistor ladder is to: generate a plurality of pad voltages based on the voltage level at the I/O pad; and supply the plurality of pad voltages to the first bias voltage generation circuit, the second bias voltage generation circuit, and the third bias voltage generation circuit.

In Example 19, the subject matter of Examples 14-18 includes, wherein the pull-up driver circuit is coupled to supply voltage of approximately about 1.8V or 3.3V and a voltage level at the I/O pad is smaller than or equal to approximately about 5V.

Example 20 is a method for manufacturing an interface circuit, the method comprising: coupling a first set of PMOS transistors to form a pull-up driver circuit; coupling a first set of NMOS transistors to form a pull-down driver circuit, the pull-down driver circuit coupled to the pull-up driver circuit; coupling a second set of PMOS transistors to form a driver-supporting circuit, the driver-supporting circuit coupled to the first set of PMOS transistors and the first set of NMOS transistors; coupling a resistor ladder to the driver-supporting circuit and an input/output (I/O) pad of the interface circuit; generating a plurality of bias voltages based on a voltage level at the I/O pad and a plurality of voltages generated by the resistor ladder; and supplying one or more of the plurality of bias voltages to the pull-up driver circuit, the pull-down driver circuit, and the driver-supporting circuit.

Example 21 is at least one machine-readable medium including instructions that, when executed by processing circuitry, cause the processing circuitry to perform operations to implement any of Examples 1-20.

Example 22 is an apparatus comprising means to implement any of Examples 1-20.

Example 23 is a system to implement any of Examples 1-20.

Example 24 is a method to implement any of Examples 1-20.

The above description is intended to be illustrative and not restrictive. For example, the above-described examples (or one or more aspects thereof) may be used in combination with others. Other embodiments may be used, such as by one of ordinary skill in the art upon reviewing the above description. The abstract is to allow the reader to ascertain the nature of the technical disclosure quickly. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An interface circuit comprising:
a first PMOS transistor comprising a drain terminal coupled to rail voltage;
a second PMOS transistor comprising a drain terminal coupled to a source terminal of the first PMOS transistor, and a bulk terminal of the first PMOS transistor coupled to a bulk terminal of the second PMOS transistor;
a third PMOS transistor comprising a drain terminal coupled to a source terminal of the second PMOS transistor; and
a fourth PMOS transistor comprising a drain terminal coupled to a source terminal and a gate terminal of the third PMOS transistor.

2. The interface circuit of claim 1, further comprising:
a first NMOS transistor comprising a drain terminal coupled to the source terminal of the second PMOS transistor and the drain terminal of the third PMOS transistor.

3. The interface circuit of claim 2, further comprising:
a second NMOS transistor comprising a drain terminal coupled to a source terminal of the first NMOS transistor and a gate terminal coupled to a gate terminal of the first NMOS transistor.

4. The interface circuit of claim 3, wherein a gate terminal and a source terminal of the fourth PMOS transistor are coupled to the drain terminal of the second NMOS transistor.

5. The interface circuit of claim 3, further comprising:
a third NMOS transistor comprising a drain terminal coupled to a source terminal of the second NMOS transistor.

6. The interface circuit of claim 5, further comprising:
a fourth NMOS transistor comprising a drain terminal coupled to a source terminal of the second NMOS transistor.

7. The interface circuit of claim 6, wherein a source terminal of the fourth NMOS transistor, a bulk terminal of the first NMOS transistor, a bulk terminal of the second NMOS transistor, a bulk terminal of the third NMOS transistor, and a bulk terminal of the fourth NMOS transistor are coupled to each other.

8. The interface circuit of claim 7, wherein a gate terminal of the second PMOS transistor is coupled to a first bias voltage, and a gate terminal of the second NMOS transistor is coupled to a second bias voltage.

9. The interface circuit of claim 8, wherein a bulk terminal of the third PMOS transistor, a bulk terminal of the fourth PMOS transistor, the bulk terminal of the first PMOS transistor, and the bulk terminal of the second PMOS transistor are coupled to a third bias voltage.

10. The interface circuit of claim 9, comprising:
a first bias voltage generation circuit coupled to the gate terminal of the second PMOS transistor;
a second bias voltage generation circuit coupled to the gate terminal of the second NMOS transistor; and
a third bias voltage generation circuit coupled to the bulk terminal of the third PMOS transistor.

11. The interface circuit of claim 1, further comprising:
a resistor ladder coupled to the drain terminal of the third PMOS transistor; and
a pad terminal coupled to the resistor ladder via a ballast resistor.

12. The interface circuit of claim 6, wherein the interface circuit comprises a system-on-chip (SoC), the SoC comprising an integrated circuit (IC), the IC comprising at least two transistors of the first PMOS transistor, the second PMOS transistor, the third PMOS transistor, the fourth PMOS transistor, the first NMOS transistor, the second NMOS transistor, the third NMOS transistor, and the fourth NMOS transistor.

13. The interface circuit of claim 12, wherein the SoC further comprises at least one connector, and wherein the at least one connector conforms with at least one of Universal Serial Bus (USB), High-Definition Multimedia Interface (HDMI), Thunderbolt, Peripheral Component Interconnect Express (PCIe), and Ethernet specifications.

14. An apparatus comprising:
a driver stage comprising a pull-up driver circuit coupled to a pull-down driver circuit;
a driver-supporting circuit coupled to the pull-up driver circuit and the pull-down driver circuit;
a resistor ladder coupled to the driver-supporting circuit; and
an electrostatic discharge (ESD) protection circuitry coupled to the resistor ladder and an input/output (I/O) pad.

15. The apparatus of claim 14, further comprising:
a first bias voltage generation circuit coupled to the pull-up driver circuit, the first bias voltage generation circuit to generate a first bias voltage for the pull-up driver circuit based on a voltage level at the I/O pad.

16. The apparatus of claim 15, further comprising:
a second bias voltage generation circuit coupled to the pull-down driver circuit, the second bias voltage generation circuit to generate a second bias voltage for the pull-down driver circuit based on the voltage level at the I/O pad.

17. The apparatus of claim 16, further comprising:
a third bias voltage generation circuit coupled to the pull-up driver circuit and the driver-supporting circuit, the third bias voltage generation circuit to generate a third bias voltage for bulk terminals of the pull-up driver circuit and the driver-supporting circuit based on the voltage level at the I/O pad.

18. The apparatus of claim 17, wherein the resistor ladder is to:
generate a plurality of pad voltages based on the voltage level at the I/O pad; and
supply the plurality of pad voltages to the first bias voltage generation circuit, the second bias voltage generation circuit, and the third bias voltage generation circuit.

19. The apparatus of claim 14, wherein the pull-up driver circuit is coupled to supply voltage of approximately about 1.8V or 3.3V and a voltage level at the I/O pad is smaller than or equal to approximately about 5V.

20. A process of making an interface circuit, comprising:
coupling a first set of PMOS transistors to form a pull-up driver circuit;
coupling a first set of NMOS transistors to form a pull-down driver circuit, the pull-down driver circuit coupled to the pull-up driver circuit;
coupling a second set of PMOS transistors to form a driver-supporting circuit, the driver-supporting circuit coupled to the first set of PMOS transistors and the first set of NMOS transistors; and
coupling a resistor ladder to the driver-supporting circuit and an input/output (I/O) pad of the interface circuit to generate a plurality of bias voltages of the pull-up driver circuit, the pull-down driver circuit, and the driver-supporting circuit based on a voltage level at the I/O pad of the interface circuit.
